(19) United States
(12) Patent Application Publication
(10) Pub. No.: US 2025/0084527 A1
(43) Pub. Date: Mar. 13, 2025

(54) SUBSTRATE HOLDER FOR MASS PRODUCTION OF SURFACE-ENHANCED RAMAN SCATTERING SUBSTRATES

(71) Applicant: Tsinghua University, Beijing (CN)

(72) Inventors: Zhengjun ZHANG, Beijing (CN); Yihang FAN, Beijing (CN); Zhenghe WANG, Beijing (CN)

(21) Appl. No.: 18/956,225

(22) Filed: Nov. 22, 2024

Related U.S. Application Data
(63) Continuation-in-part of application No. 17/132,210, filed on Dec. 23, 2020, now abandoned.

(51) Int. Cl. C23C 14/50; C23C 14/02; C23C 14/30; G01N 21/65

(52) U.S. Cl. CPC C23C 14/50; C23C 14/021; C23C 14/30; G01N 21/658

(57) ABSTRACT

The disclosure belongs to the technical field of trace organic matter detection, and relates to a substrate holder for mass production of surface-enhanced Raman scattering (SERS) substrates. The substrate holder includes a ring-shaped body and a support frame thereof. A plurality of cones are disposed on the ring-shaped body, and a plurality of substrates are pasted on both surfaces of each cone. The substrate holder disclosed in disclosure allows for simultaneous deposition of silver nanorods on a plurality of substrates by glancing angle deposition method. An array film composed of the silver nanorods of a plurality of substrates has good product homogeneity, and the production efficiency of a traditional preparation method can be improved.

### TECHNICAL FIELD

The disclosure belongs to the technical field of trace organic matter detection, and in particular, relates to a substrate holder for mass production of surface-enhanced Raman scattering (SERS) substrates.

### BACKGROUND

Surface-enhanced Raman scattering (SERS), as a trace matter detection approach, has been widely used in the fields of environmental pollutant detection, food safety monitoring, disease diagnoses and medical care, etc. for its advantages such as high sensitivity, rapid detection, low cost and non-destructive analysis. High sensitive SERS substrates are typically prepared from noble metals such as gold, silver or copper, where silver nanostructured substrates presented the most outstanding SERS effects. Nobel metals are expensive, and the method of electron beam evaporation may result in wasting of abundant raw materials as the raw materials were mostly deposited on the chamber wall due to spherical spatial diffusion. Meanwhile, this will induce insufficient production of SERS substrates as substrates with only couple of inches in diameter can be produced in a typical process.

To overcome the shortcoming, the disclosure follows a glancing angle deposition technique as the basic principle, where the direction of a beam from an evaporation source forms an angle of 86-87 degrees with a substrate's normal direction, and a substrate holder with circular arc structures is employed to paste more substrates, so that evaporated raw material can be used fully and the included angle of desired 86-87 degrees between each substrate's normal direction and the evaporation beam can be guaranteed. The holder will enable mass production of SERS substrates with homogeneous nanostructures and outstanding detecting performance

### SUMMARY

The disclosure aims to design a substrate holder for mass production of surface-enhanced Raman scattering (SERS) substrates.

To achieve the above objective, the disclosure adopts the following technical solution: a substrate holder for mass production of SERS substrates includes a ring-shaped body and a support frame thereof. A plurality of cones are disposed on the ring-shaped body, and a plurality of substrates are pasted on both surfaces of each cone.

Upper and bottom edges of each cone are circular curves.

All the cones are located in a vertical direction.

Each circular curve has a cone angle of 6-8 degrees, and a bisector of the cone angle is in the vertical direction.

A method for preparing SERS substrates with the substrate holder includes the following steps:
(1) preprocessing substrates;
(2) pasting the preprocessed substrates on the substrate holder;
(3) aligning the substrate holder to an evaporation source;
(4) vacuumizing an electron beam evaporation chamber; and
(5) depositing a slanted nanorod array film on the substrates on the substrate holders to form SERS substrates.

Further, in step (1), the preprocessing includes ultrasonic cleaning of single side polished silicon substrates using acetone, absolute ethyl alcohol and deionized water in sequence, and drying of the substrates in the air.

Further, in step (2), the substrates are uniformly distributed on two surfaces of the cones.

Further, in step (3), the evaporation source is a crucible which is located under the center of a circle of the ring-shaped body; and the direction of a beam from the evaporation source forms an angle of 86 degrees with each substrate's normal direction.

Further, in step (4), the electron beam evaporation chamber has a vacuum degree of 4*10⁻⁴ Pa.

Further, in step (5), the depositing is carried out at room temperature with metal silver as a target material, and a deposition rate of the silver is controlled at 5 Å/s, such that a slanted silver nanorod array film having a length of about 600 nm in total is deposited on the substrates of the substrate holder.

The disclosure has the following advantages: the substrate holder disclosed herein allows for simultaneous deposition of silver nanorods on a plurality of substrates by a glancing angle deposition method. An array film composed of the silver nanorods of a plurality of substrates has good product homogeneity, and the production efficiency of a traditional preparation method can be improved.

### BRIEF DESCRIPTION OF THE DRAWINGS

FIG. 1 is an external view of a substrate holder according to an example of the present disclosure.

FIG. 2 is a scanning electron microscope image of a silver nanorod array SERS substrate deposited according to an example of the present disclosure.

FIG. 3 is an enhanced Raman signal chart of R6G molecules of a silver nanorod array prepared according to an example of the present disclosure.

FIG. 4 is an external view of a ring-shaped body of the substrate holder according to an example of the present disclosure.

FIG. 5 is an external view of a cone of the substrate holder according to an example of the present disclosure.

FIG. 6 is an external view of a support frame of the substrate holder according to an example of the present disclosure.

FIG. 7 is a schematic diagram of a method for preparing SERS substrates with the substrate holder according to an example of the present disclosure.

### DETAILED DESCRIPTION

According to the present disclosure, a plurality of silver nanorod array surface-enhanced Raman scattering (SERS) substrates may be deposited simultaneously on a substrate holder by a glancing angle deposition method.

The structure of the substrate holder is introduced below. The substrate holder 1 for mass production of SERS substrates includes a ring-shaped body 11 and a support frame 12 thereof. A plurality of cones 20 are disposed on the ring-shaped body 11.

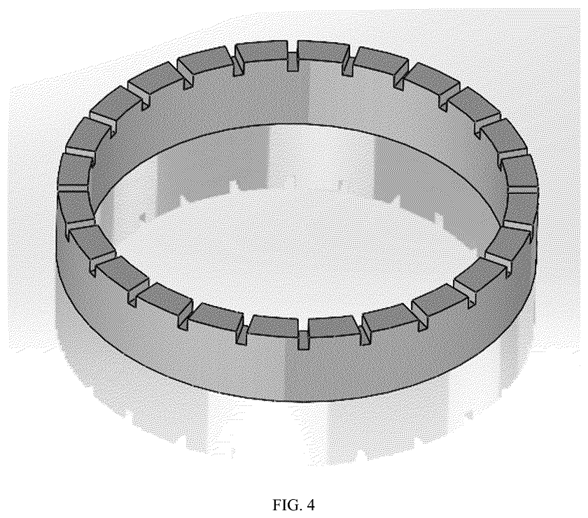

As shown in FIG. 4, the ring-shaped body 11 is a ring-shaped, and there are slots on the ring-shaped body 11 for clamping the cone 20.

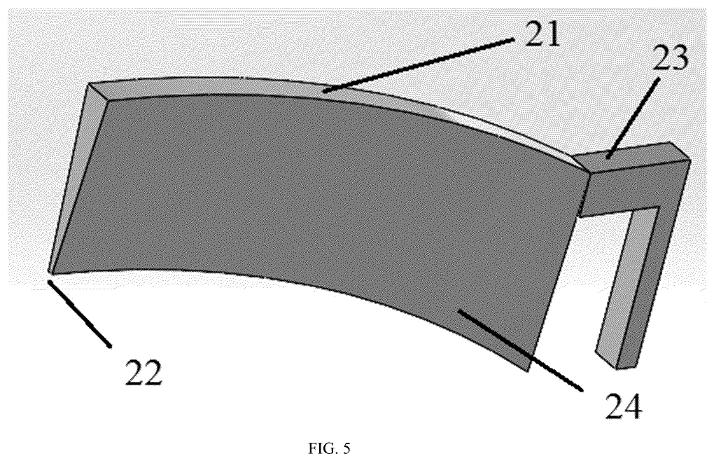

As shown in FIG. 5, the cone 20 has an upper edge 21, a bottom edge 22, a handle 23 for clamping the cone on the ring-shaped body, and two surfaces 24 for pasting substrates. Two surfaces of each cone 24 are used to paste a plurality of substrates 21 thereon. The upper and bottom edges of each cone are circular curves.

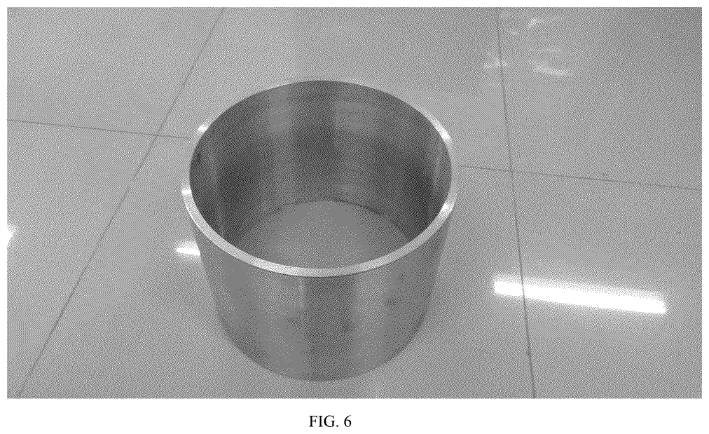

As shown in FIG. 6, the support frame 12 is used to support the ring-shaped body 11.

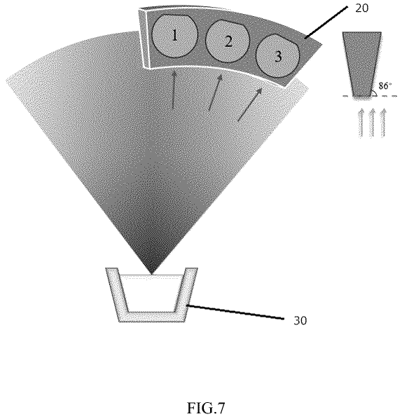

A method for preparing SERS substrates with the substrate holder includes the following steps:
(1) preprocessing substrates;
(2) As shown in FIG. 7, pasting the preprocessed substrates on the surfaces of each cone 20;
(3) As shown in FIG. 7, aligning the substrate holder to an evaporation source 30, the center of the concentric circles formed by the circular curves of upper and bottom edges of each cone is exactly at the center of the evaporation source 30;
(4) vacuumizing an electron beam evaporation chamber; and
(5) depositing a slanted nanorod array film on the substrates on the substrate holders by physical vapor deposition to form SERS substrates.

All the cones are located in a vertical direction. Each circular curve has a cone angle of 6-8 degrees, and a bisector of the cone angle is in the vertical direction.

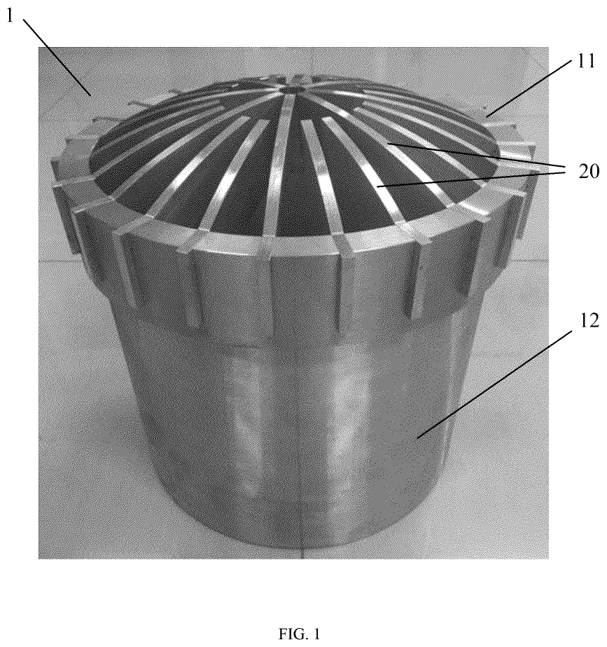

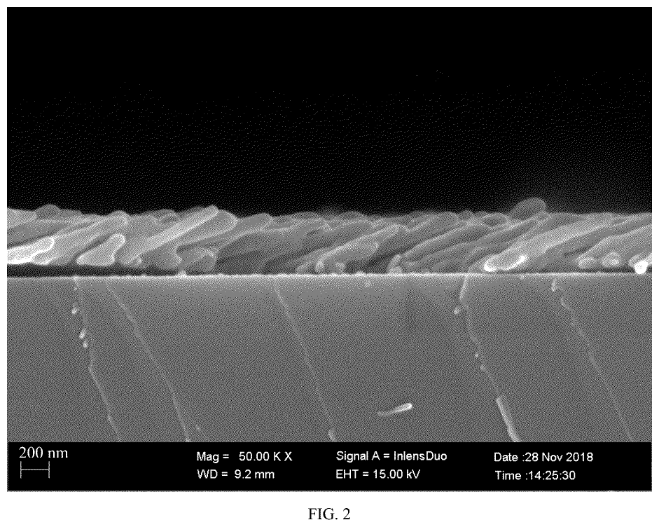

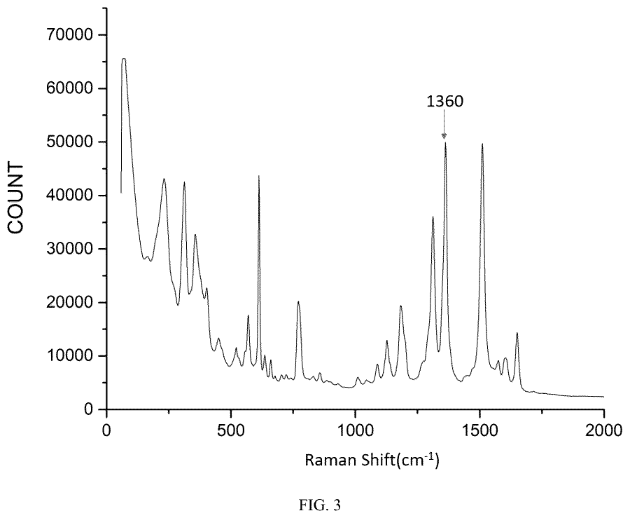

The disclosure will be described in detail in conjunction with FIG. 1 to FIG. 3 and an example. The following example is illustrative rather than limiting, and the protection scope of the disclosure cannot be limited by the following example.

### Example 1

(1) Single side polished silicon substrates were subjected to ultrasonic cleaning using acetone, absolute ethyl alcohol and deionized water in sequence, and dried in the air.

(2) The preprocessed substrates were pasted on a substrate holder.

(3) The center of outer circle of a ring-shaped body of the substrate holder was aligned to a crucible, the center of the concentric circles formed by the circular curves of upper and bottom edges of each cone is exactly at the center of the crucible.

(4) At room temperature, metal silver was used as a target material, and a chamber of a two-electron beam evaporation coating machine was vacuumized to a vacuum degree of 4*10⁻⁴ Pa.

(5) Adjustment was performed, and a deposition ratio of the silver was controlled at 5 Å/s such that a slanted silver nanorod film having a length of about 600 nm in total was deposited on the substrates of the substrate holder;

(6) A 10⁻⁵ mol/L R6G solution was prepared.

(7) The SERS substrates prepared in steps (1) to (5) were immersed in the solution to be detected prepared in step (6) for 30 minutes.

(8) The SERS substrates with trace amount of R6G absorbed thereon in step (6) were placed in a Raman spectrometer, and a light source with a wavelength of 785 nm was selected for measurement of Raman spectra.

It could be observed that peak intensity R6G signals of several substrates were basically the same, and it could be seen that the silver nanorod arrays on the substrates were almost the same in morphology, indicating that the SERS substrates prepared with the sample holder had almost the same effects. Thus, the expected objective was achieved.

The above example presents a detailed description of the technical solution of the present disclosure. Apparently, the disclosure is not limited to the described example. Those skilled in the art can also make various changes based on the example of the present disclosure, but any change that is equivalent or similar to the disclosure shall fall within the protection scope of the present disclosure.

What is claimed is:

1. A substrate holder for mass production of surface-enhanced Raman scattering (SERS) substrates, comprising a ring-shaped body and a support frame thereof, wherein the ring-shaped body have slots with a plurality of cones clamped in the slots of the ring-shaped body, and a plurality of substrates are pasted on two surfaces of each cone.

2. The substrate holder according to claim 1, wherein upper and bottom edges of each cone are circular curves.

3. The substrate holder according to claim 2, wherein all the cones are located in a vertical direction.

4. The substrate holder according to claim 2, wherein each circular curve has a cone angle of 6-8 degrees, and a bisector of the cone angle is in the vertical direction.

5. A method for preparing SERS substrates with the substrate holder according to claim 2, comprising the following steps:
(1) preprocessing substrates;
(2) pasting the preprocessed substrates on the substrate holder;
(3) aligning the substrate holder to an evaporation source, the center of the concentric circles formed by the circular curves of upper and bottom edges of each cone is exactly at the center of the evaporation source;
(4) vacuumizing an electron beam evaporation chamber; and
(5) depositing a slanted nanorod array film on the substrates on the substrate holders to form SERS substrates.

6. A method for preparing SERS substrates with the substrate holder according to claim 3, comprising the following steps:
(1) preprocessing substrates;
(2) pasting the preprocessed substrates on the substrate holder;
(3) aligning the substrate holder to an evaporation source, the center of the concentric circles formed by the circular curves of upper and bottom edges of each cone is exactly at the center of the evaporation source;
(4) vacuumizing an electron beam evaporation chamber; and
(5) depositing a slanted nanorod array film on the substrates on the substrate holders to form SERS substrates.

7. A method for preparing SERS substrates with the substrate holder according to claim 4, comprising the following steps:
(1) preprocessing substrates;
(2) pasting the preprocessed substrates on the substrate holder;
(3) aligning the substrate holder to an evaporation source, the center of the concentric circles formed by the circular curves of upper and bottom edges of each cone is exactly at the center of the evaporation source;
(4) vacuumizing an electron beam evaporation chamber; and
(5) depositing a slanted nanorod array film on the substrates on the substrate holders to form SERS substrates.

8. The method according to claim 5, wherein in step (1), the preprocessing comprises ultrasonic cleaning of single side polished silicon substrates using acetone, absolute ethyl alcohol and deionized water in sequence, and drying of the substrates in the air.

9. The method according to claim 6, wherein in step (1), the preprocessing comprises ultrasonic cleaning of single side polished silicon substrates using acetone, absolute ethyl alcohol and deionized water in sequence, and drying of the substrates in the air.

10. The method according to claim 7, wherein in step (1), the preprocessing comprises ultrasonic cleaning of single side polished silicon substrates using acetone, absolute ethyl alcohol and deionized water in sequence, and drying of the substrates in the air.

11. The method according to claim 5, wherein in step (2), the substrates are uniformly distributed on two surfaces of the cones.

12. The method according to claim 6, wherein in step (2), the substrates are uniformly distributed on two surfaces of the cones.

13. The method according to claim 7, wherein in step (2), the substrates are uniformly distributed on two surfaces of the cones.

14. The method according to claim 5, wherein in step (3), the evaporation source is a crucible which is located under the center of a circle of the ring-shaped body; and the direction of a beam from the evaporation source forms an angle of 86 degrees with each substrate's normal direction.

15. The method according to claim 6, wherein in step (3), the evaporation source is a crucible which is located under the center of a circle of the ring-shaped body; and the direction of a beam from the evaporation source forms an angle of 86 degrees with each substrate.

16. The method according to claim 5, wherein in step (4), the electron beam evaporation chamber has a vacuum degree of 4*10⁻⁴ Pa.

17. The method according to claim 5, wherein in step (5), the depositing is carried out at room temperature with metal silver as a target material, and a deposition rate of the silver is controlled at 5 Å/s such that a slanted silver nanorod array film having a length of about 600 nm in total is deposited on the substrates of the substrate holder.
